(19) United States
(12) Patent Application Publication
(10) Pub. No.: US 2011/0175157 A1
(43) Pub. Date: Jul. 21, 2011

(54) NONVOLATILE SEMICONDUCTOR MEMORY DEVICE AND METHOD FOR MANUFACTURING SAME

(75) Inventors: Katsuyuki SEKINE, Mie-ken (JP); Tetsuya Kai, Kanagawa-ken (JP); Yoshio Ozawa, Kanagawa-ken (JP)

(73) Assignee: Kabushiki Kaisha Toshiba, Tokyo (JP)

(21) Appl. No.: 13/008,469

(22) Filed: Jan. 18, 2011

(30) Foreign Application Priority Data
Jan. 18, 2010 (JP) 2010-008128

(51) Int. Cl. H01L 29/792; H01L 21/336

(52) U.S. Cl. 257/324; 438/591; 257/E29.309; 257/E21.423

(57) ABSTRACT

According to one embodiment, a nonvolatile semiconductor memory device includes a semiconductor layer; first and second insulating layers; a functional layer; first and second gate electrodes. The first insulating layer opposes the semiconductor layer. The second insulating layer is provided between the semiconductor layer and the first insulating layer. The functional layer is provided between the first and second insulating layers. The second gate electrode is separated from the first gate electrode. The first insulating layer is disposed between the first gate electrode and the semiconductor layer and between the second gate electrode and the semiconductor layer. The charge storabilities in first and second regions of the functional layer are different from that of a third region of the functional layer. The first and second regions oppose the first and second gate electrodes, respectively. The third region is between the first and the second regions.

### CROSS-REFERENCE TO RELATED APPLICATIONS

This application is based upon and claims the benefit of priority from the prior Japanese Patent Application No. 2010-008128, filed on Jan. 18, 2010; the entire contents of which are incorporated herein by reference.

### FIELD

Embodiments described herein relate generally to a nonvolatile semiconductor memory device and a method for manufacturing the same.

### BACKGROUND

Memory devices using a charge storage layer, for example, MONOS (Metal Oxide Nitride Oxide Semiconductor) type memory devices are developed.

In such memory devices, when the charge storage layer is continuously provided between cells, charges may move between the cells and charge holding characteristics may be deteriorated in some cases. Although the charge holding characteristics are tried to be maintained by dividing the charge storage layer between cells in a plane type MONOS cell, cost is increased because the number of processes increases. Also in a collectively patterned three-dimensionally stacked MONOS memory device as described in JP-A 2007-266143 (Kokai), a charge storage layer continues between cells. The conventional technologies have room for improvement from a view point of the charge holding characteristics.

### BRIEF DESCRIPTION OF THE DRAWINGS

FIG. 1A and FIG. 1B are schematic cross-sectional views illustrating the configuration of a nonvolatile semiconductor memory device according to a first embodiment;

FIG. 2 is a schematic cross-sectional view illustrating the configuration of a nonvolatile semiconductor memory device according to a first example;

FIG. 3 is a schematic perspective view illustrating the configuration of a nonvolatile semiconductor memory device according to a second example;

FIG. 4 is a schematic perspective view illustrating the configuration of a memory unit of the nonvolatile semiconductor memory device according to the second example;

FIG. 5 is a schematic cross-sectional view illustrating the configuration of the nonvolatile semiconductor memory device according to the second example;

FIG. 6 is a schematic perspective view illustrating the configuration of a nonvolatile semiconductor memory device according to a third example;

FIG. 7A and FIG. 7B are schematic cross-sectional views illustrating the configuration of a nonvolatile semiconductor memory device according to a second embodiment; and

FIG. 8 is a flowchart illustrating a method for manufacturing a nonvolatile semiconductor memory device according to a third embodiment.

### DETAILED DESCRIPTION

In general, according to one embodiment, a nonvolatile semiconductor memory device including: a semiconductor layer; a first insulating layer; a second insulating layer; a functional layer; a first gate electrode; and a second gate electrode. The first insulating layer opposes the semiconductor layer. The second insulating layer is provided between the semiconductor layer and the first insulating layer. The functional layer is provided between the first insulating layer and the second insulating layer. The first insulating layer is disposed between the first gate electrode and the semiconductor layer. The second gate electrode is separated from the first gate electrode. The first insulating layer is disposed between the second gate electrode and the semiconductor layer. A charge storability in a first region of the functional layer and a charge storability in a second region of the functional layer are different from a charge storability in a third region of the functional layer. The first region opposes the first gate electrode. The second region opposes the second gate electrode. The third region is provided between the first region and the second region.

Embodiments will now be described with reference to the drawings.

The drawings are schematic or conceptual; and the relationships between the thicknesses and widths of portions, the proportional coefficients of sizes among portions, etc., are not necessarily the same as the actual values thereof. Further, the dimensions and the proportional coefficients may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

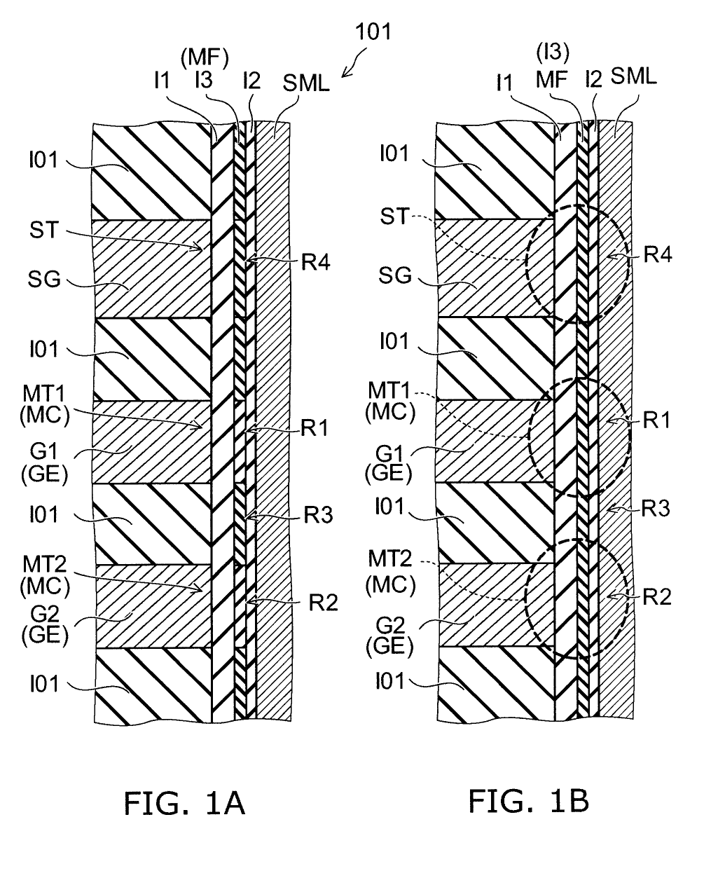

FIG. 1A and FIG. 1B are schematic cross-sectional views illustrating the configuration of a nonvolatile semiconductor memory device according to the first embodiment.

Namely, FIG. 1A illustrates the configuration of the nonvolatile semiconductor memory device 101 according to the embodiment, and FIG. 1B illustrates the state in a halfway of the manufacturing process of the nonvolatile semiconductor memory device 101.

As illustrated in FIG. 1A, the nonvolatile semiconductor memory device 101 according to the embodiment includes a semiconductor layer SML, a first insulating layer I1, a second insulating layer I2, a functional layer I3, a first gate electrode G1, and a second gate electrode G2.

The first insulating layer I1 opposes the semiconductor layer SML.

The second insulating layer I2 is provided between the semiconductor layer SML and the first insulating layer I1.

The functional layer I3 is provided between the first insulating layer I1 and the second insulating layer I2.

The first gate electrode G1 and the second gate electrode G2 are provided on a side of the first insulating layer I1 opposite to the semiconductor layer SML. In other words, the first insulating layer I1 is disposed between the first gate electrode G1 and the semiconductor layer SML. The first insulating layer I1 is disposed between the second gate electrode G2 and the semiconductor layer SML. The first gate electrode G1 and the second gate electrode G2 are separated from each other.

A first memory transistor MT1 is formed in a portion of the first gate electrode G1. A second memory transistor MT2 is formed in a portion of the second gate electrode G2. The first memory transistor MT1 and the second memory transistor MT2 serve as a cell MC of the nonvolatile semiconductor memory device 101.

An inter-layer insulating film I01 is provided between the first gate electrode G1 and a selection gate electrode SG described below and between the second gate electrode G2 and the selection gate electrode SG.

In the first memory transistor MT1 and the second memory transistor MT2, the first insulating layer I1 functions as a block insulating film. In the first memory transistor MT1 and the second memory transistor MT2, the second insulating layer I2 functions as a tunnel insulating film. For example, silicon oxide is used for the first insulating layer I1 and the second insulating layer I2.

In the first memory transistor MT1 and the second memory transistor MT2, the functional layer I3 functions as a charge storage layer which stores information.

In the nonvolatile semiconductor memory device 101 according to the embodiment, the functional layer I3 which functions as the charge storage layer is continuously provided also between the first memory transistor MT1 and the second memory transistor MT2.

The functional layer I3 has a first region R1 opposing the first gate electrode G1, a second region R2 opposing the second gate electrode G2, and a third region R3 provided between the first region R1 and the second region R2. The third region R3 corresponds to a region between the first memory transistor MT1 and the second memory transistor MT2.

In the nonvolatile semiconductor memory device 101, the charge storability in the first region R1 and the charge storability in the second region R2 are different from that of the third region R3.

Here, the charge storability is a grade to capture injected charges. For example, in the functional layer I3, traps which accumulate charges are distributed spatially and the density of the traps is different in the functional layer I3. The traps exist inside the functional layer I3, near the interface of the functional layer I3 on the first insulating layer I1 side, and near the interface of the functional layer I3 on the second insulating layer I2 side, and the like. When the density of the traps differs, the charge storability differs. In the case where the functional layer I3 has multiple stacked films, the traps are formed in the interface between the stacked films, and the like. When such traps have different densities, the charge storabilities are different.

For example, the charge storability in the first region R1 and the charge storability in the second region R2 are higher than the charge storability in the third region R3.

For example, in the first region R1 and the second region R2, the densities of the traps are higher than that in the third region R3.

For example, the functional layer I3 is formed from a parent body film MF serving as the charge storage layer. By applying an electric field and/or applying a current to the parent body film MF, the state of the parent body film MF is changed and the charge storability is increased.

For example, as illustrated in FIG. 1B, the functional layer I3 is formed from the parent body film MF.

The charge storability in the first region R1 of the functional layer I3 is made to be higher than that of the parent body film MF by applying an electric field between the first gate electrode G1 and the semiconductor layer SML. The charge storability in the first region R1 of the functional layer I3 is made to be higher than that of the parent body film MF by applying a current between the first gate electrode G1 and the semiconductor layer SML.

Similarly, the charge storability in the second region R2 of the functional layer I3 is made to be higher than that of the parent body film MF by applying an electric field between the second gate electrode G2 and the semiconductor layer SML. The charge storability the second region R2 of the functional layer I3 is made to be higher than that of the parent body film MF by applying a current between the second gate electrode G2 and the semiconductor layer SML.

Thereby, the charge storability in the first region R1 and the charge storability in the second region R2 are made to be higher than the charge storability in the third region R3.

In other words, for the parent body film MF, a film is used in which the charge storability is increased or the charge storability is generated for the first time by applying an electric field and/or applying a current. By selectively applying an electric field and/or applying a current to portions of the parent body film MF corresponding to the first memory transistor MT1 and the second memory transistor MT2, the parent body film MF functions as the charge storage layer in the first memory transistor MT1 and the second memory transistor MT2. In other words, the first region R1 (i.e., a portion between the first gate electrode G1 of the functional layer I3 and the semiconductor layer SML) and the second region R2 (a portion between the second gate electrode G2 of the functional layer I3 and the semiconductor layer SML) function as the charge storage layer.

In the region between the first memory transistor MT1 and the second memory transistor MT2 (the third region R3), the parent body film MF does not function as the charge storage layer. Therefore, the movement of the charge is suppressed even when the parent body film MF (the functional layer I3) is continuously provided in the region between the first memory transistor MT1 and the second memory transistor MT2. Thereby, the charge holding characteristic can be improved.

For the parent body film MF, for example, SiO₂ having an oxygen composition ratio higher than the stoichiometric ratio, SiO₂ containing an impurity, SiO₂ containing hydrogen, SiN containing hydrogen and the like can be used.

In addition, for the parent body film MF, a stacked film of a silicon nitride film and a silicon oxide film; a stacked film of a silicon oxide film and a silicon nitride film containing fluorine; a silicon nitride film having a composition of excessive nitrogen; a silicon oxide film having a composition of excessive oxygen; a stacked film of a silicon nitride film having a composition of excessive nitrogen and a silicon oxide film having a composition of excessive oxygen; and the like can be used. Here, “composition of excessive nitrogen” means “composition of nitrogen higher than the composition of nitrogen with the stoichiometric ratio”, and “composition with excessive oxygen” means “composition of oxygen higher than the composition of oxygen with the stoichiometric ratio.”

In order to obtain a wide memory window for multiple values, it is preferable to use materials based on a silicon nitride film for the parent body film MF. Especially, a silicon nitride film containing hydrogen and/or fluorine is preferable. In the case where the charge holding characteristic is emphasized, it is preferable to use materials based on a silicon oxide film.

Thus, in the nonvolatile semiconductor memory device 101, the charge storability in the first region R1 of the functional layer I3 opposing the first gate electrode G1 and the charge storability in the second region R2 of the functional layer 13 opposing the second gate electrode G2 are different from that of the third region R3 of the functional layer I3 provided between the first region R1 and the second region R2.

The functional layer I3 is formed from the parent body film MF. Then, the charge storability in the first region R2 and the charge storability in the second region R2 are made to be higher than the charge storability in the parent body film MF by implementing at least one of applying an electric field between the first gate electrode G1 and the semiconductor layer SML and between the second gate electrode G2 and the semiconductor layer SML and applying a current between the first gate electrode G1 and the semiconductor layer SML and between the second gate electrode G2 and the semiconductor layer SML. Thereby, the charge storability in the first region R1 and the charge storability in the second region R2 are made to be higher than that of the third region R3. Thereby, the charge holding characteristic can be improved.

As illustrated in FIG. 1A and FIG. 1B, the nonvolatile semiconductor memory device 101 further includes a selection gate electrode SG provided on a side of the first insulating layer I1 opposite to the semiconductor layer SML. The selection gate electrode SG is separated from the first gate electrode G1 and the second gate electrode G2. In other words, the first insulating layer I1 is disposed between the selection gate electrode SG and the semiconductor layer SML. A selection gate transistor ST is formed in a portion of the selection gate electrode SG.

The functional layer I3 extends also in the portion of the selection gate electrode SG. The charge storability in a fourth region R4 of the functional layer I3 opposing the selection gate electrode SG is different from those of the first region R1 and the second region R2. More specifically, the charge storability in the fourth region R4 of the functional layer I3 opposing the selection gate electrode SG is lower than those of the first region R1 and the second region R2.

For example, the charge storability in the first region R1 and the charge storability in the second region R2 are made to be higher than that of the parent body film MF by implementing at least one of applying an electric field and applying a current between the first gate electrode G1 and the semiconductor layer SML and between the second gate electrode G2 and the semiconductor layer SML. The electric field at this time is set to be comparatively high. Also, the current at this time is set to be comparatively large.

Such a high electric field or such a large current is not applied between the selection gate electrode SG and the semiconductor layer SML. Thereby, the charge storability in the fourth region R4 is maintained at a low state similar to that of the parent body film MF.

Thereby, even when the structure of the selection gate transistor ST is the same as those of the first memory transistor MT1 and the second memory transistor MT2, the threshold shift of the selection gate transistor ST can be suppressed.

In other words, the first memory transistor MT1 and the second memory transistor MT2 include a stacked structure of the first insulating layer I1, the second insulating layer I2, and the functional layer I3. Similarly, the selection gate transistor ST includes a stacked structure of the first insulating layer I1, the second insulating layer I2, and the functional layer I3. Thus, the configurations of the stacked films are the same. By making the charge storability in the selection gate transistor ST (i.e., the fourth region R4) to be lower than the charge storabilities in the functional layer I3 in the first memory transistor MT1 and the second memory transistor MT2 (i.e., the first region R1 and the second region R2), the threshold shift of the selection gate transistor ST can be suppressed.

For example, in the operation of the selection gate transistor ST, the electric field applied between the selection gate electrode SG and the semiconductor layer SML is set to be lower than the electric field applied between the first gate electrode G1 and the semiconductor layer SML and between the second gate electrode G2 and the semiconductor layer SML in order to make the charge storability in the first region R1 and the charge storability in the second region R2 to be higher than that of the parent body film MF.

In the operation of the selection gate transistor ST, the current applied between the selection gate electrode SG and the semiconductor layer SML is set to be smaller than the current applied between the first gate electrode G1 and the semiconductor layer SML and between the second gate electrode G2 and the semiconductor layer SML in order to make the charge storability in the first region R1 and the charge storability in the second region R2 to be higher than that of the parent body film MF.

In other words, in the operation of the selection gate transistor ST, a voltage applied between the selection gate electrode SG and the semiconductor layer SML is set to be lower than a voltage applied between the first gate electrode G1 and the semiconductor layer SML and between the second gate electrode G2 and the semiconductor layer SML in order to make the charge storability in the first region R1 and the charge storability in the second region R2 to be higher than that of the parent body film MF.

Thus, for the functional layer I3, a film (the parent body film MF) is used in which the charge storability is generated for the first time by applying a current and/or applying a voltage to the cell MC or the charge storability is made to be higher than that after forming the cell MC by applying a current and/or applying a voltage to the cell MC. Thereby, since the charge storability is obtained in the cell MC part, the threshold shift of the selection gate transistor ST is suppressed even when the selection gate electrode SG part has the same structure as that of the cell MC part. Since the charge storage function is given only to the cell MC portion, the movement of the charges in a lateral direction via the functional layer I3 can be suppressed, and the charge holding characteristic of the cell MC can be improved.

If the charge storage layer used for the memory transistor MT is provided also in the selection gate transistor ST, the threshold of the selection gate transistor ST changes with time. Therefore, in conventional nonvolatile semiconductor memory devices, suppressing the change with time has been tried by making the configuration of the selection gate transistor ST to be different from that of the memory transistor MT. However, this caused an increase of processes and an increase in cost. On the other hand, the change with time described above can be suppressed by applying this embodiment even when the configuration of the selection gate transistor is the same as that of the memory transistor MT. Therefore, the processes can be skipped and the cost can be reduced.

Hereinafter, an example of a method for forming the parent body film MF will be described.

In the case where a silicon nitride film containing hydrogen is used for the parent body film MF, the silicon nitride film can be made to contain hydrogen by the following methods.

For example, a silicon nitride film with a thickness of 5 nm to 10 nm is formed by an LPCVD method using hexachlorodisilane and NH3 or using dichlorosilane and NH3 at a temperature of 500° C. to 700° C., for example, and then the silicon nitride film is exposed to plasma containing hydrogen only or hydrogen and nitrogen. Thereby, the silicon nitride film can be made to contain hydrogen.

For example, the silicon nitride film may be formed by a PECVD method, in which hexachlorodisilane and NH3 or dichlorosilane and NH3 are introduced into a plasma atmosphere, at a temperature of 300° C. to 500° C.

The silicon nitride film formed by such methods contains much hydrogen, and the trap density in the silicon nitride film is very low before an electric stress is applied. By applying the electric stress, the trap density in the silicon nitride film is increased.

The film-forming temperature and the temperature of a plasma treatment are preferable to be as low as possible because much hydrogen can be contained.

In the case where a silicon oxide film containing hydrogen is used for the parent body film MF, the silicon oxide film can be made to contain hydrogen by the following methods.

For example, a silicon oxide film is formed by the PLCVD method using dichlorosilane and N2O at a temperature of 700° C. to 800° C., for example, and then, the silicon oxide film is exposed to plasma containing oxygen and hydrogen. Thereby, the silicon oxide film can be made to contain hydrogen.

The silicon oxide film may be formed by an ALD method using an oxidizer and a silicon precursor based on an organic metal source at a low temperature, e.g., a room temperature to 500° C. It is more preferable to use the ALD method because much oxygen is also contained.

For the parent body film MF, a silicon oxide film containing fluorine or a silicon nitride film containing fluorine may be used. In these cases, the silicon oxide film or the silicon nitride film can be made to contain fluorine by the following methods.

For example, when forming the silicon oxide film and the silicon nitride film described above, a method can be used in which a gas containing fluorine of very small quantity is supplied to a film-forming atmosphere simultaneously to be contained in the silicon oxide film and the silicon nitride film.

Also, a method can be used in which fluorine is introduced into the parent body film MF by a direct ion implantation. Further, a method can be used in which fluorine is introduced into the parent body film MF by performing a heat treatment to diffuse fluorine into the parent body film ML after introducing fluorine into a substrate, a conductive layer, and the like included in the nonvolatile semiconductor memory device by an ion implantation.

In the nonvolatile semiconductor memory device 101 according to the embodiment, the number of gate electrodes GE is arbitrary. In the above, a description about a part of a plurality of the gate electrodes GE is provided. The configuration of the functional layer I3 in other gate electrodes GE can be made to be the same as those in the first region R1 and the second region R2, and the configuration of the functional layer I3 between gate electrodes GE can be made to be the same as that of the third region R3.

### First Example

The first example according to the embodiment is an example of a plane type nonvolatile semiconductor memory device.

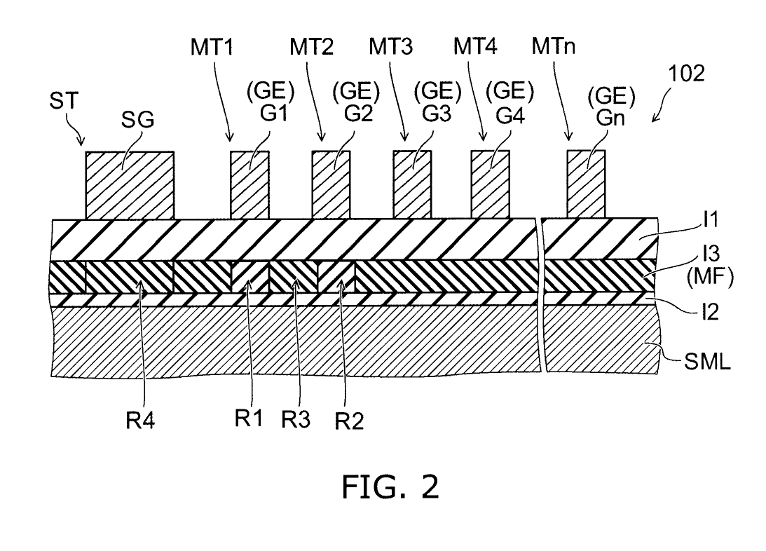

FIG. 2 is a schematic cross-sectional view illustrating the configuration of the nonvolatile semiconductor memory device according to the first example.

As illustrated in FIG. 2, in the nonvolatile semiconductor memory device 102 of the first example, the second insulating layer I2 is provided on the semiconductor layer SML. For the semiconductor layer SML, a semiconductor substrate such as a silicon substrate is used. The second insulating layer I2 is the tunnel insulating film and includes, for example, a silicon oxide film or a silicon oxynitride film in major proportions. The thickness of the second insulating layer I2 is, for example, 2 nm (nanometers) to 6 nm.

On the second insulating layer I2, the parent body film MF serving as the functional layer I3 is provided. The parent body film MF is a film that the charge storability is increased or the charge storability is generated by applying an electric field and/or applying a current. The thickness of the parent body film MF may be set 5 nm to 10 nm.

The first insulating layer I1 is provided on the functional layer I3 (the parent body film MF). The first insulating layer I1 is the block insulating film and includes, for example, a silicon oxide film, a silicon oxynitride film, a high dielectric constant insulating film, and the like. It is preferable for the high dielectric constant insulating film to include, for example, an alumina with a large band gap in major proportions. The thickness of the first insulating layer I1 may be set, for example, 10 nm to 25 nm.

A conductive film is provided on the first insulating layer I1, and the conductive film is patterned to form the first gate electrode G1, the second gate electrode G2, the third gate electrode G3, the fourth gate electrode G4, the n-th gate electrode Gn, and the selection gate electrode SG, for example. Here, “n” is an integer not less than 2. The value of n is arbitrary.

For the conductive film, polysilicon, metal (including alloys) with a high work function, various kinds of silicide, and the like are used.

Thereby, the first to the n-th memory transistors MT1 to MTn and the selection gate transistor ST are formed.

In the example of FIG. 2, a state is illustrated in which at least one of applying the electric field and applying the current between the first gate electrode G1 and the semiconductor layer SML and between the second gate electrode G2 and the semiconductor layer SML is implemented. In other words, a state is illustrated in which a voltage for processing described above is not applied to the third gate electrode G3, the fourth gate electrode G4, and the n-th gate electrode Gn. The voltage for the processing described above may be applied to all the first gate electrode G1 to the n-th gate electrodes Gn.

In this specific example, at least one of applying the electric field and applying the current between the first gate electrode G1 and the semiconductor layer SML and between the second gate electrode G2 and the semiconductor layer SML is implemented and the charge storability in the parent body film MF is increased partially. In other words, the charge storability in the first region R1 corresponding to the first gate electrode G1 and the charge storability in the second region R2 corresponding to the second gate electrode G2 are higher than that of the third region R3 corresponding to between the first memory transistor MT1 and the second memory transistors MT2.

Thereby, even if the functional layer I3 of the third region R3 continues between the first memory transistor MT1 and the second memory transistor MT2, the movement of the charges can be suppressed because the charge holding ability in the third region R3 is lower than those of the first region R1 and the second region R2. Thereby, the nonvolatile semiconductor memory device having a good charge holding characteristic can be provided.

Further, even when the structure of the selection gate transistor ST is the same as those of the first memory transistor MT1 and the second memory transistor MT2, the threshold shift of the selection gate transistor ST can be suppressed.

In the nonvolatile semiconductor memory device 102, since a process of dividing the functional layer I3 serving as the charge storage layer for every cell MC is skipped, the productivity is high, and the charge holding characteristic can be improved without an increase of cost.

Thus, in this embodiment, the charge storability of the cell MC is generated for the first time or the charge storability is increased by applying the electric stress to the cell MC after forming the structure of the cell MC.

For example, although the trap density of the parent body film MF is uniform immediately after forming the structure of the cells MC, the trap densities of the cells MC (the first region R1 and the second region R2 of the functional layer I3) are made to be higher than the trap density between the cells MC (the third region R3 of the functional layer I3) by applying the electric stress to the cells MC. And, by applying the electric stress to the cells MC, the trap densities of the cells MC (the first region R1 and the second region R2 of the functional layer I3) is made to be higher than that of the selection gate transistor ST (the fourth region R4 of the functional layer I3).

The parent body film MF may be partially divided between the cells MC and between the selection gate electrode SG and the cells MC, for example.

Hereinafter, an example of a method for making the charge storability in the first region R1 and the charge storability in the second region R2 of the functional layer I3 to be different from that of the third region R3, i.e., a method for initialization of the cells MC will be described.

Hereinbelow, a case is described in which a silicon nitride film containing hydrogen is used for the parent body film MF.

For example, taking the potential of the semiconductor layer SML as a reference, a pulse having a width from 1 ns (nanosecond) to 1 μs (microsecond) is applied to the first gate electrode G1 and the second gate electrode G2 at a voltage from +10 V (volts) to +25 V or from −10 V to −25 V. The application of the pulse may be performed multiple times.

A positive pulse having a width from 1 ns to 1 μs at a voltage from +10 V to +20 V and a negative pulse having a width from 1 ns to 1 μs at a voltage from −10 V to −20 V may be applied. The order of application of the positive pulse and application of the negative pulse is arbitrary in this case. The positive pulse and the negative pulse described above may be applied multiple times in combination.

By applying the voltage described above to the first gate electrode G1 and the second gate electrode G2, hydrogen separates from the silicon nitride film containing hydrogen and the charge storability is increased in portions (the first region R1 and the second region R2) of the parent body film ML where the voltage is applied and the current is flowed, for example. In other words, the charge storage layers of the cells MC are formed. And, in a region (for example, the third region R3) of the parent body film MF where the voltage is not applied, the state of the parent body film MF is not changed and the charge storability is not increased.

Thus, for the films in which the bonds in the films are cut and the charge storage characteristic is generated (or increased) by the initialization processing (application of the electric field and/or application of the current), a silicon oxide film containing hydrogen; a stacked film of a silicon oxide film and a silicon nitride film containing fluorine; a silicon nitride film having a composition of excessive nitrogen; and a silicon oxide film having a composition of excessive oxygen; and the like can be applied.

If the positive pulse and the negative pulse are alternatively applied multiple times, the charge storability in the parent body film MF is increased more. More charges can be stored in functioning as the charge storage layer of each cell MC, and it becomes advantageous.

It is preferable that the absolute value of the voltage applied for the initialization processing of the cells MC is higher than the absolute value of the voltage applied for programming and erasing in functioning as the charge storage layer of the cells MC by not less than 1 V. Thereby, the characteristics of programming and erasing of the cells MC are stabilized.

It is preferable that the temperature in implementing the initialization processing is higher than the temperature of the cells MC in use of the nonvolatile semiconductor memory device. When the initialization processing is performed at a high temperature, in the parent body film MF, hydrogen is separated more easily and the charge storability can be increased more. By performing the initialization processing at a high temperature, the charge becomes difficult to be trapped in the parent body film MF in the initialization processing, and the charge holding characteristic is stabilized in use of the nonvolatile semiconductor memory device after the initialization processing is completed. When the temperature in performing the initialization processing is high, there are merits in which the time of the initialization processing can be shortened and the productivity can be improved.

### Second Example

The second example according to the embodiment is an example of a collectively patterned three-dimensionally stacked semiconductor memory device. The configuration of the embodiment is applied to each charge storage layer of the memory transistor serving as a memory unit of the collectively patterned three-dimensionally stacked semiconductor memory device.

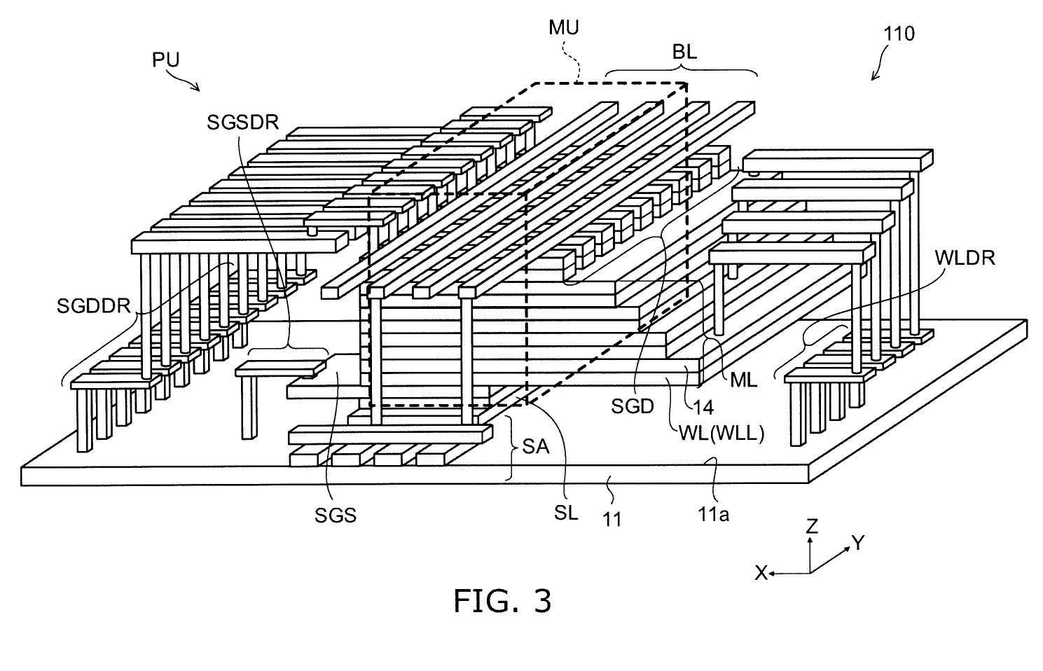

FIG. 3 is a schematic perspective view illustrating the configuration of the nonvolatile semiconductor memory device according to the second example.

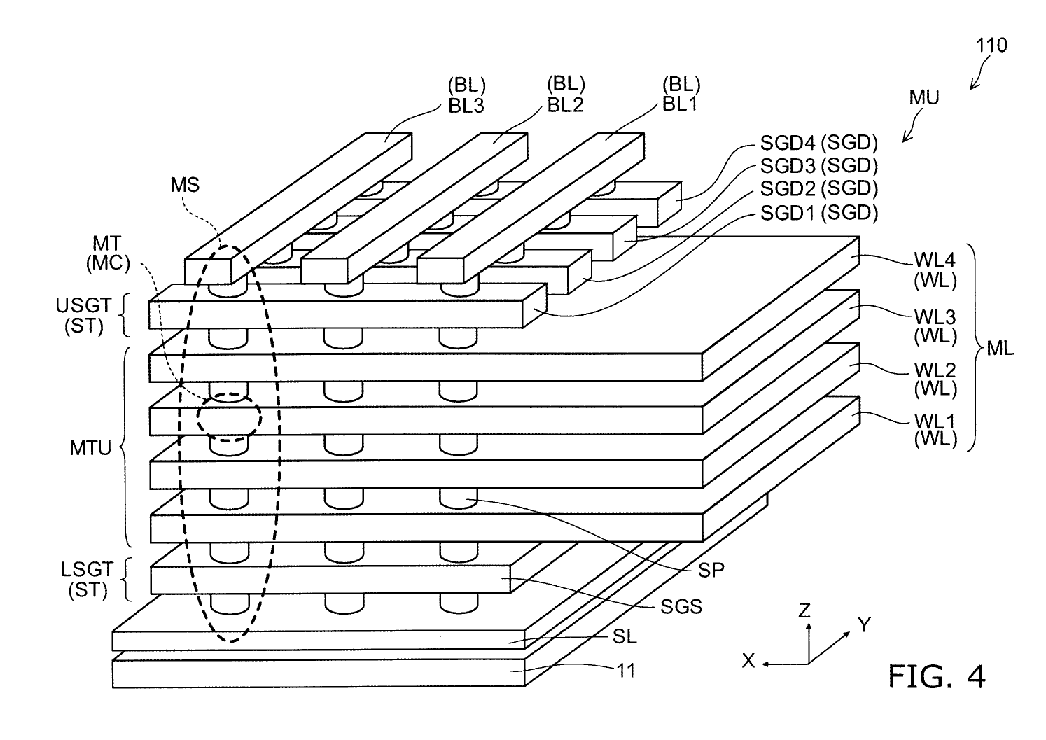

FIG. 4 is a schematic perspective view illustrating the configuration of the memory unit of the nonvolatile semiconductor memory device according to the second example.

In FIG. 3 and FIG. 4, only the conductive portions are shown and the insulative portions are omitted for easier viewing of the drawings.

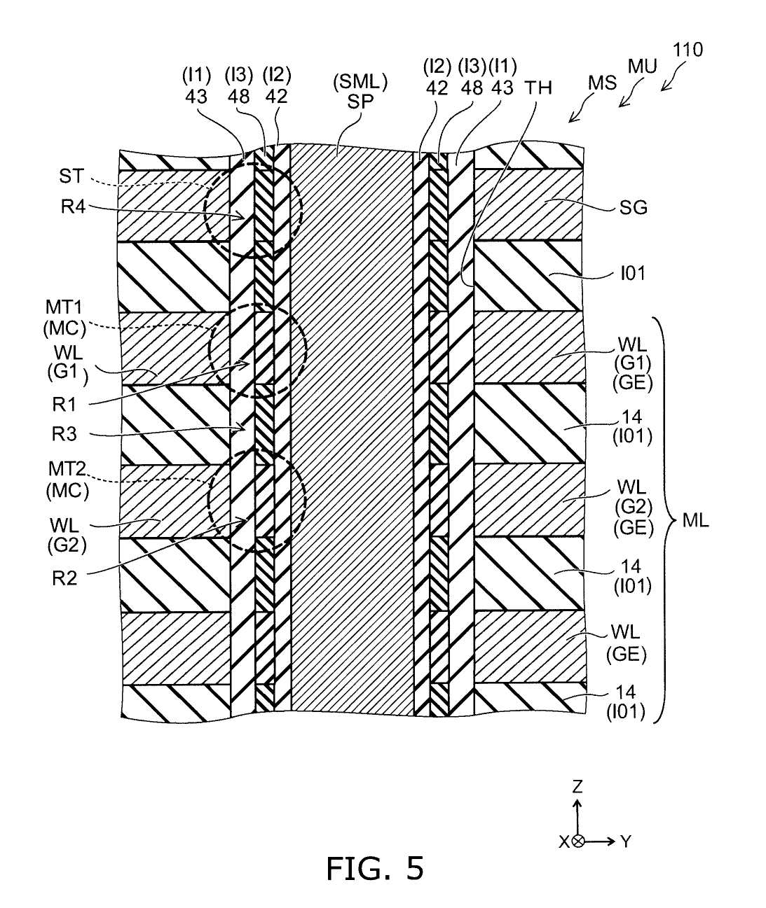

FIG. 5 is a schematic cross-sectional view illustrating the configuration of the nonvolatile semiconductor memory device according to the second example.

As illustrated in FIG. 3, for example, a memory unit MU, and a peripheral circuit unit PU are provided in the nonvolatile semiconductor memory device 110. The memory unit MU and the peripheral circuit unit PU are provided on a major surface 11a of a substrate 11 made of, for example, a single crystal silicon.

Here, a direction perpendicular to the major surface 11a of the substrate 11 is taken as a Z-axis direction (a first direction). One direction in a plane parallel to the major surface 11a is taken as a Y-axis direction (a second direction). A direction perpendicular to the Z-axis and the Y-axis is taken as an X-axis direction (a third direction).

In the memory unit MU, a stacked structure body ML in which a plurality of electrode films WL and a plurality of inter-electrode insulating films 14 are alternatively stacked is provided. A semiconductor pillar SP (not illustrated) piercing the stacked structure body ML along the Z-axis direction is provided. The semiconductor pillars SP serve as a plurality of memory strings MS (not illustrated) extending along the Z-axis direction. The electrode films WL function as word lines WLL. In the stacked structure body ML, the number of the electrode films WL provided and the number of the inter-electrode insulating films provided 14 are arbitrary.

The electrode film WL corresponds to the gate electrode GE, and the inter-electrode insulating film 14 corresponds to the inter-layer insulating film I01.

A plurality of bit lines BL extending in the Y-axis direction are provided above the stacked structure body ML (on a side opposite to the substrate 11), and each of the bit lines BL is connected to each of the memory strings MS. A drain-side selection gate electrode SGD is provided between the stacked structure body ML and the bit line BL. The drain-side selection gate electrode SGD extends along, for example, the X-axis direction and is connected to a drain-side selection gate line drive circuit SGDDR.

Source lines SL are provided below the stacked structure body ML (on the substrate 11 side). The source lines SL are connected to the memory strings MS, respectively. A source-side selection gate electrode SGS is provided between the stacked structure body ML and the source lines SL. The source-side selection gate electrode SGS is connected to a source-side selection gate line drive circuit SGSDR.

Each of the word lines WLL (the electrode films WL) is connected to a word line drive circuit WLDR, and each of the bit lines BL is connected to, for example, a sense amplifier SA.

The drain-side selection gate line drive circuit SGDDR, the source-side selection gate line drive circuit SGSDR, the word line drive circuit WLDR, and the sense amplifier SA are included in the peripheral circuit unit PU.

As illustrated in FIG. 4, the semiconductor pillars SP piercing the stacked structure body ML along the Z-axis direction are provided. Memory transistors MT (the cells MC) are provided at portions where semiconductor pillars SP and each of the electrode films WL (for example, WL1 to WL4) intersect. The plurarily of memory transistors MT are arranged along the Z-axis direction and serve as a memory transistor unit MTU.

Above the stacked structure body ML, upper selection gate transistors USGT are provided at portions where the drain-side selection gate electrode SGD (for example, SGD1 to SGD4) and the semiconductor pillars SP intersect. On the other hand, below the stacked structure body ML, lower selection gate transistors LSGT are provided at portions where the source-side selection gate electrode SGS and the semiconductor pillars SP intersect.

The upper selection gate transistors USGT and the lower selection gate transistors LSGT correspond to the selection gate transistors ST.

The upper selection gate transistor USGT, the memory transistor unit MTU, and the lower selection gate transistor LSGT are included in the memory string MS. Each of the memory strings MS function as one NAND string.

The upper end of each of the memory strings MS is connected to the bit lines BL (for example, BL1 to BL3). The lower end of each of the memory strings MS is connected to the source line SL.

FIG. 5 illustrates the configuration of a part of the memory unit MU and is a drawing when cutting the memory unit MU by a Y-Z plane, for example.

As illustrated in FIG. 5, the nonvolatile semiconductor memory device 110 includes the stacked structure body ML having the plurality of electrode films WL and the plurality of the inter-electrode insulating films 14 stacked alternatively in the Z-axis direction; the semiconductor pillar SP piercing the stacked structure body ML along the Z-axis direction; a memory layer 48; an inside insulating film 42; and an outside insulating film 43.

The outside insulating film 43 corresponds to the first insulating layer I1, the inside insulating film 42 corresponds to the second insulating layer I2, and the memory layer 48 corresponds to the functional layer I3.

The memory layer 48 is provided between each of the electrode films WL and the semiconductor pillar SP. The inside insulating film 42 is provided between the memory layer 48 and the semiconductor pillar SR The outside insulating film 43 is provided between each of the electrode films WL and the memory layer 48.

The inside insulating film 42, the memory layer 48, and the outside insulating film 43 are tubular (the shape of a pipe), respectively. The inside insulating film 42, the memory layer 48, and the outside insulating film 43 have the shape of a concentric cylinder taking an axis extending in the Z-axis direction of the semiconductor pillar SP as the central axis. The inside insulating film 42, the memory layer 48, and the outside insulating film 43 are disposed in this order from the inside toward the outside.

For example, the outside insulating film 43, the memory layer 48, and the inside insulating film 42 are formed in this order on the wall surface inside a through-hole TH piercing the stacked structure body ML along the Z-axis direction. A semiconductor is filled into a remaining space thereof to form the semiconductor pillar SP.

The shape of the through-hole TH cutting by the X-Y plane is, for example, circular (including shapes such as an ellipse and a flat circle besides the shape of an exact circle).

In this specific example, the semiconductor pillar SP is a pillar shape having no void or no other members included inside. However, the semiconductor pillar SP may be tubular extending along the Z-axis direction. In the case where the semiconductor pillar SP is tubular, a core material portion made of an insulative material may be provided inside the tubular shape or a void may be provided inside the tubular shape. For example, a seam portion may be provided in the center portion of the semiconductor pillar SP when the outside insulating film 43, the memory layer 48, the inside insulating film 42, and the semiconductor pillar SP are formed in this order on the inner wall surface of the through-hole TH. Hereinbelow, a case is described where the semiconductor pillar SP is the pillar shape.

Cells MC are provided in intersection portions of the electrode films WL of the stacked structure body ML and the semiconductor pillar SP. In other words, in the portions where the electrode films WL and the semiconductor pillar SP intersect, the memory transistors MT having the memory layer 48 are provided in the shape of a three-dimensional matrix. By storing charges in the memory layers 48, each of the memory transistors MT functions as the cell MC which memorizes data.

The inside insulating film 42 functions as the tunnel insulating film in the memory transistor MT of the cell MC. On the other hand, the outside insulating film 43 functions as the block insulating film in the memory transistor MT of the cell MC. The inter-electrode insulating film 14 functions as the inter-layer insulating film which isolates the electrode films WL from each other.

For the electrode films WL, any conductive materials can be used. For example, amorphous silicon or polysilicon silicon provided with conductivity can be used, or a metal, an alloy, and the like also can be used. In this specific example, amorphous silicon or polysilicon is used for the electrode film WL.

A silicon oxide film can be used for the inter-electrode insulating film 14, the inside insulating film 42, and the outside insulating film 43. The inter-electrode insulating film 14, the inside insulating film 42, and the outside insulating film 43 may be a single film or may be a stacked film. The inter-electrode insulating film 14, the inside insulating film 42, and the outside insulating film 43 are not limited to the materials recited above. Any insulating materials can be used for those films.

The memory layer 48 (the functional layer I3) is continuously provided in a region between the memory transistors MT (for example, the first memory transistor MT1 and the second memory transistor MT2).

The memory layer 48 (the functional layer I3) has the first region R1 opposing the first gate electrode G1, the second region R2 opposing the second gate electrode G2, and the third region R3 provided between the first region R1 and the second region R2. The charge storability in the first region R1 and the charge storability in the second region R2 are different from that of the third region R3. Specifically, the charge storability in the first region R1 and the charge storability in the second region R2 are higher than the charge storability in the third region R3.

For example, the memory layer 48 (the functional layer 13) is formed from the parent body film MF serving as the charge storage layer. By applying an electric field and/or a current to the parent body film MF, the state of the parent body film MF is changed and the charge storability is increased.

Thus, the nonvolatile semiconductor memory device 110 further includes the inter-electrode insulating film 14 and the substrate 11. The inter-electrode insulating film 14 is provided between the first gate electrode G1 and the second gate electrode G2. The first gate electrode G1 and the second gate electrode G2 are disposed on the substrate 11. The first direction from the first gate electrode G1 toward the second gate electrode G2 is perpendicular to the major surface 11a of the substrate 11. The semiconductor layer SML opposes the side face of the first gate electrode G1 along the first direction and the side face of the second gate electrode G2 along the first direction. In this specific example, the semiconductor layer SML pierces the first gate electrode G1, the inter-electrode insulating film 14, and the second gate electrode G2 along the first direction. The first insulating layer I1 is disposed between the side face of the semiconductor layer SML and the first gate electrode G1 and between the side face of the semiconductor layer SML and the second gate electrode G2.

Also according to the nonvolatile semiconductor memory device 110 of the second example having such a configuration, the nonvolatile semiconductor memory device having a good charge holding characteristic can be provided.

In the collectively patterned three-dimensionally stacked semiconductor memory devices as described above, it is difficult to divide the memory layer 48 (the functional layer I3) for every cell MC after forming the memory layer 48 (the functional layer I3). Thus, the effect of applying this embodiment is exerted more effectively.

### Third Example

The third example according to the embodiment is also an example of the collectively patterned three-dimensionally stacked semiconductor memory device.

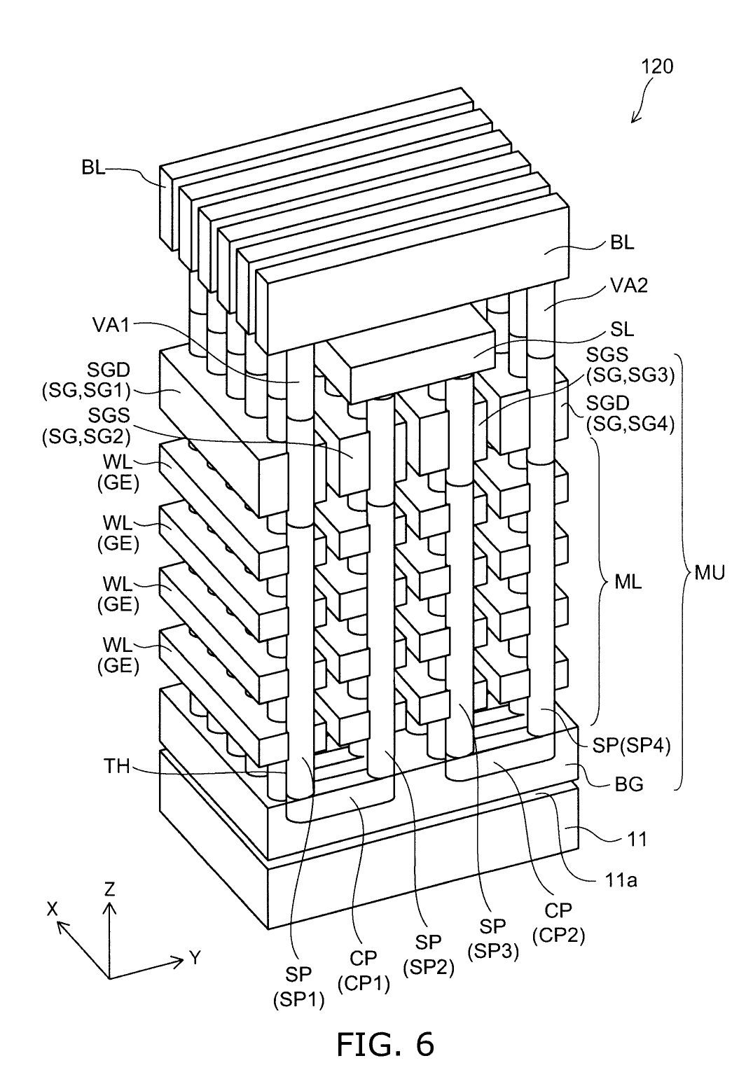

FIG. 6 is a schematic perspective view illustrating the configuration of the nonvolatile semiconductor memory device according to the third example.

In this drawing, only the conductive portions are shown and the insulative portions are omitted for easier viewing of the drawing.

As illustrated in FIG. 6, in the nonvolatile semiconductor memory device 120, two semiconductor pillars SP are connected by a connecting portion CR

In other words, the nonvolatile semiconductor memory device 120 includes the stacked structure body ML having the plurality of electrode films WL (corresponding to the gate electrodes GE) and the plurality of the inter-electrode insulating films 14 stacked alternatively in the Z-axis direction; a first semiconductor pillar SP1 piercing the stacked structure body ML along the Z-axis direction; the memory layer 48; the inside insulating film 42; and the outside insulating film 43. The first semiconductor pillar SP1 is one of the semiconductor pillars SP described previously.

In this specific example, the electrode films WL are divided, for example, along the Y-axis direction, and the electrode films WL extend in the X-axis direction.

The nonvolatile semiconductor memory device 120 further includes a second semiconductor pillar SP2 and a first connecting portion CP1 (the connecting portion CP). The second semiconductor pillar SP2 is one of the semiconductor pillars SP described previously.

The second semiconductor pillar SP2 is juxtaposed with the first semiconductor pillar SP1, for example, in the Y-axis direction and pierces the stacked structure body ML along the Z-axis direction.

The memory layer 48 (corresponding to the functional layer I3) is provided also between each of the electrode films WL and the second semiconductor pillar SP2. The inside insulating film 42 (corresponding to the second insulating layer I2) is provided also between the second semiconductor pillar SP2 and the memory layer 48. The outside insulating film 43 (corresponding to the first insulating layer I1) is provided also between the electrode film WL and the memory layer 48 of the second semiconductor pillar SP2.

The first connecting portion CP1 electrically connects the first semiconductor pillar SP1 and the second semiconductor pillar SP2 on the same side (the substrate 11 side) in the Z-axis direction. The first connecting portion CP1 is provided to extend along the Y-axis direction. For the first connecting portion CP1, the same material as the first and second semiconductor pillars SP1 and SP2 is used.

For example, a back gate BG (a connecting portion conductive layer) is provided on the major surface 11a of the substrate 11 via an inter-layer insulating film. A trench is provided in a portion of the back gate BG opposing the first and second semiconductor pillars SP1 and SP2, and films serving as the outside insulating film 43, the memory layer 48, and the inside insulating film 42, respectively, are formed inside the trench. The connecting portion CP made of a semiconductor is filled into the remaining space. The forming of the films, which serves as the outside insulating film 43, the memory layer 48 and the inside insulating film 42, and the connecting portion CP in the trench is performed simultaneously and collectively with the forming of the outside insulating film 43, the memory layer 48, the inside insulating film 42 and the semiconductor pillar SP in the through-hole TH. Thus, the back gate BG is provided to oppose the connecting portion CR

Thereby, a U-shaped semiconductor pillar is made by the first and second semiconductor pillars SP1 and SP2 and the connecting portion CP, and this serves as a U-shaped NAND string.

As illustrated in FIG. 6, an end of the first semiconductor pillar SP1 on a side opposite to the first connecting portion CP1 is connected to the bit line BL, and an end of the second semiconductor pillar SP2 on a side opposite to the first connecting portion CP1 is connected to the source line SL. The semiconductor pillar SP and the bit line BL are connected by a via VA1 and a via VA2.

In this specific example, the bit line BL extends along the Y-axis direction, and the source line SL extends along the X-axis direction.

Between the stacked structure body ML and the bit line BL, the drain-side selection gate electrode SGD (a first selection gate electrode SG1) is provided to oppose the first semiconductor pillar SP1, and the source-side selection gate electrode SGS (a second selection gate electrode SG2) is provided to oppose the second semiconductor pillar SP2. Thereby, programming of desired data and reading can be performed on any cells MC of any semiconductor pillars SP.

The drain-side selection gate electrode SGD and the source-side selection gate electrode SGS are included in the selection gate electrode SG.

Any conductive materials can be used for the selection gate electrode SG. For example, polysilicon or amorphous silicon can be used. In this specific example, the selection gate electrode SG is divided along the Y-axis direction and has a stripe shape extending along the X-axis direction.

Thus, the selection gate electrode SG is provided above the stacked structure body ML (the furthest side from the substrate 11), a through-hole is provided in the selection gate electrode SG, the selection gate insulating film of the selection gate transistor is provided in the internal surface, and a semiconductor is filled into the inner side. This semiconductor is included in the semiconductor pillar SP.

The source line SL is provided above the selection gate electrode SG, and the bit line BL is provided above source line SL. The bit line BL has a stripe shape along the Y-axis direction.

At one end and one other end in the X-axis direction, the electrode films WL are connected to the word interconnections by the via-plugs and are electrically connected with the drive circuit provided on the substrate 11, for example. At this time, the length in the X-axis direction of each of the electrode films WL stacked along the Z-axis direction is changed in a staircase pattern. An electric connection between the stacked electrode films WL and the drive circuit is performed at the ends of the X-axis direction.

As illustrated in FIG. 6, the nonvolatile semiconductor memory device 120 can further include a third semiconductor pillar SP3, a fourth semiconductor pillar SP4, and a second connecting portion CP2. The third semiconductor pillar SP3 and the fourth semiconductor pillar SP4 are included in the semiconductor pillars SP, and the second connecting portion CP2 is included in the connecting portions CR

The third semiconductor pillar SP3 is juxtaposed with the second semiconductor pillar SP2 in the Y-axis direction on a side of the second semiconductor pillar SP2 opposite to the first semiconductor pillar SP1 and pierces the stacked structure body ML along the Z-axis direction. The fourth semiconductor pillar SP4 is juxtaposed with the third semiconductor pillar SP3 in the Y-axis direction on a side of the third semiconductor pillar SP3 opposite to the second semiconductor pillar SP2 and pierces the stacked structure body ML along the Z-axis direction.

The second connecting portion CP2 electrically connects the third semiconductor pillar SP3 and the fourth semiconductor pillar SP4 on the same side (the same side as the first connecting portion CP1) in the Z-axis direction. The second connecting portion CP2 is provided to extend along the Y-axis direction and opposes the back gate BG.

The memory layer 48 is provided also between each of electrode films WL and the third semiconductor pillar SP3, and between each of electrode films WL and the fourth semiconductor pillar SP4, and between the back gate BG and the second connecting portion CP2. The inside insulating film 42 is provided also between the third semiconductor pillar SP3 and the memory layer 48, between the fourth semiconductor pillar SP4 and the memory layer 48, and between the memory layer 48 and the second connecting portion CP2. The outside insulating film 43 is provided also between each of electrode films WL and the memory layer 48 of the third semiconductor pillar SP3, between each of electrode films WL and the memory layer 48 of the fourth semiconductor pillar SP4, and between the memory layer 48 of the second connecting portion CP2 and the back gate BG.

The source line SL is connected with a third end of the third semiconductor pillar SP3 on a side opposite to the second connecting portion CP2. The bit line BL is connected with a fourth end of the fourth semiconductor pillar SP4 on a side opposite to the second connecting portion CP2.

The source-side selection gate electrode SGS (a third selection gate electrode SG3) is provided to oppose the third semiconductor pillar SP3, and the drain-side selection gate electrode SGD (a fourth selection gate electrode SG4) is provided to oppose the fourth semiconductor pillar SP4.

The source-side selection gate electrode SGS and the drain-side selection gate electrode SGD are included in the selection gate electrode SG.

Also in the nonvolatile semiconductor memory device 120 having such a configuration, the memory layer 48 (the functional layer I3) is formed from the parent body film MF serving as the charge storage layer. By applying an electric field and/or a current to the parent body film MF, the state of the parent body film MF is changed and the charge storability is increased. In other words, in the memory layer 48 (the functional layer I3), the charge storability in the first region R1 and the charge storability in the second region R2 are different from that of the third region R3.

Also according to the nonvolatile semiconductor memory device 120 of the third example having such a configuration, the nonvolatile semiconductor memory device having a good charge holding characteristic can be provided.

### Second Embodiment

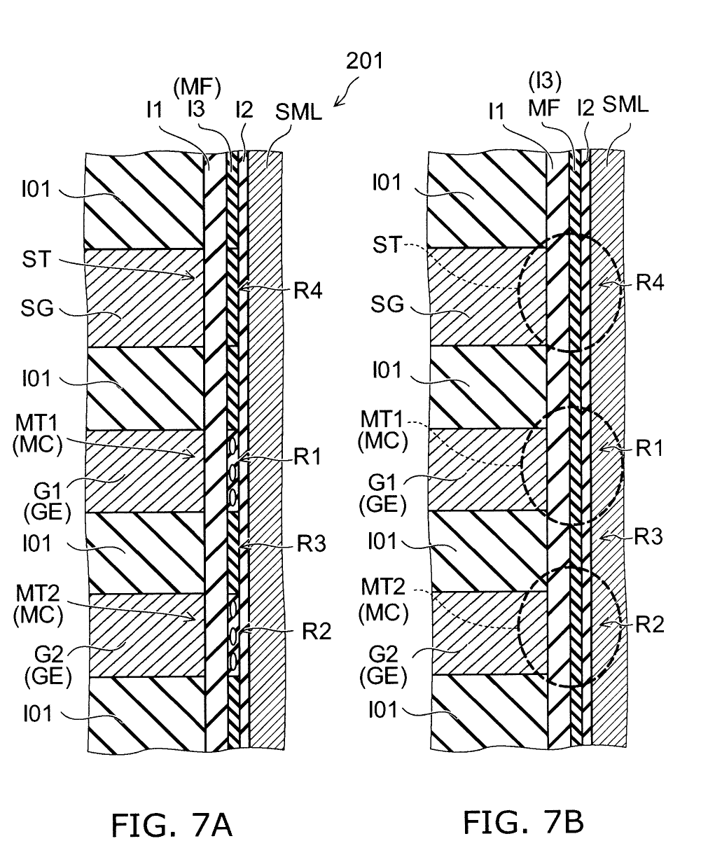

FIG. 7A and FIG. 7B are schematic cross-sectional views illustrating the configuration of a nonvolatile semiconductor memory device according to the second embodiment.

Namely, FIG. 7A illustrates the configuration of the nonvolatile semiconductor memory device 201 according to the embodiment, and FIG. 7B illustrates a state in a halfway of the manufacturing process of the nonvolatile semiconductor memory device 201.

As illustrated in FIG. 7A, the nonvolatile semiconductor memory device 201 according to the embodiment includes the semiconductor layer SML, the first insulating layer I1, the second insulating layer I2, the functional layer I3, the first gate electrode G1, and the second gate electrode G2. In the nonvolatile semiconductor memory device 201, the configurations of the semiconductor layer SML, the first insulating layer I1, the second insulating layer I2, the first gate electrode G1, and the second gate electrode G2 can be the same as those of the nonvolatile semiconductor memory device 101. Therefore, the descriptions are omitted.

In the nonvolatile semiconductor memory device 201 as well, the functional layer I3 has the first region R1 opposing the first gate electrode G1, the second region R2 opposing the second gate electrode G2, and the third region R3 between the first region R1 and the second region R2. The charge storability in the first region R1 and the charge storability in the second region R2 are different from that of the third region R3.

In the nonvolatile semiconductor memory device 201, the functional layer I3 has a charge storability immediately after the formation, and the charge storability in the first region R1 and the charge storability in the second region R2 of the functional layer I3 are changed from the state immediately after the formation.

For example, as illustrated in FIG. 7B, the functional layer I3 is formed from the parent body film MF serving as the charge storage layer. The parent body film MF has a charge storability immediately after the formation.

For the parent body film MF in this case, a thin film of a conductive material such as a thin Si film, a thin germanium film, a thin metal film can be used.

For example, by implementing at least one of applying an electric field and applying a current between the first gate electrode G1 and the semiconductor layer SML and between the second gate electrode G2 and the semiconductor layer SML, the state of the parent body film MF of the first region R1 and the second region R2 is changed, and the first region R1 and the second region R2 have a different charge storability from the third region R3.

For example, by implementing at least one of applying an electric field and applying a current between the first gate electrode G1 and the semiconductor layer SML and between the second gate electrode G2 and the semiconductor layer SML, an aggregation occurs in the parent body film MF, for example, and the parent body film MF becomes discontinuous.

In other words, a first portion with a high charge storability and a second portion with a charge storability lower than that of the first portion are formed in the first region R1 and the second region R2 of the functional layer I3. The portion of the parent body film ML where the aggregation occurs is the first portion, and the remaining portion where no aggregation occurs is the second portion. Alternatively, the portion of the parent body film ML where the aggregation occurs may be the second portion, and the remaining portion where no aggregation occurs may be the second portion.

For example, the first portion is divided by the second portion. The second portion is divided by the first portion. In other words, the first portion is provided discretely. In other words, the second portion is provided discretely.

On the other hand, in the third region R3 corresponding to the portion between the first gate electrode G1 and the second gate electrode G2, the applying of the electric field and/or the applying of the current are not implemented, and the state of the parent body film MF is not changed.

The charge storability in the first region R1 and the charge storability in the second region R2 having the portion formed discontinuously in which the state of the parent body film MF is changed are different from that of the third region R3 which is the portion being not changed. Thus, the charge storability in the first region R1 and the charge storability in the second region R2 can be made to be different from that of the third region R3.

Thus, the functional layer I3 is formed from the parent body film MF. By implementing at least one of applying an electric field and applying a current between the first gate electrode G1 and the semiconductor layer SML and between the second gate electrode G2 and the semiconductor layer SML, the first portion with a high charge storability and the second portion with a charge storability lower than that of the first portion are formed in the first region R1 and the second region R2. For example, the first portion and the second portion are provided discretely, i.e., discontinuously.

In the functional layer I3 of the first memory transistor MT1 and the second memory transistor MT2 of the nonvolatile semiconductor memory device 201, the charge holding characteristic is high because the portion which functions as the charge storage layer is disposed discontinuously. Thus, according to the nonvolatile semiconductor memory device 201, the nonvolatile semiconductor memory device having a good charge holding characteristic can be provided.

The configuration of this embodiment can be applied to the nonvolatile semiconductor memory devices 102, 110, and 120 of the first to third example described in regard to the first embodiment and nonvolatile semiconductor memory devices of modification thereof, and the same effect is exerted.

As described in regard to the first embodiment and the second embodiment, the functional layer I3 may be insulative and may be conductive (including metal and/or semiconductor).

### Third Embodiment

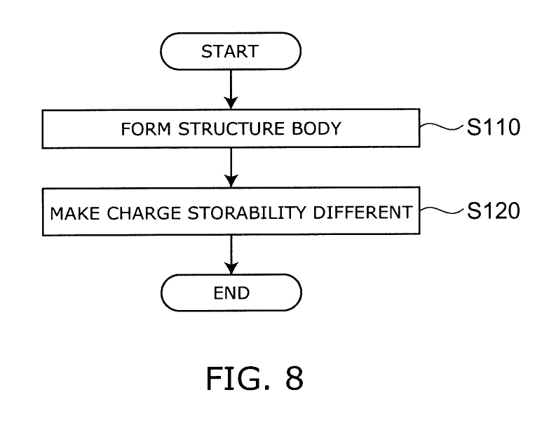

FIG. 8 is a flowchart illustrating a method for manufacturing a nonvolatile semiconductor memory device according to the third embodiment.

As illustrated in FIG. 8, the manufacturing method according to the embodiment includes forming a structure body (step S110). The structure body includes a semiconductor layer SML; a first insulating layer I1 opposing the semiconductor layer SML; a second insulating layer I2 provided between the semiconductor layer SML and the first insulating layer I1; a parent body film MF provided between the first insulating layer I1 and the second insulating layer I2; a first gate electrode G1; and a second gate electrode G2. The first insulating layer I1 is disposed between the first gate electrode G1 and the semiconductor layer SML. The second gate electrode G2 is separated from the first gate electrode G1. The first insulating layer I1 is disposed between the second gate electrode G2 and the semiconductor layer SML.

The charge storability in the first region R1 of the parent body film MF and the charge storability in the second region R2 of the parent body film MF are made to be different from the charge storability in the parent body film MF by implementing at least one of applying an electric field between the first gate electrode G1 and the semiconductor layer SML and between the second gate electrode G2 and the semiconductor layer SML and applying a current between the first gate electrode G1 and the semiconductor layer SML and between the second gate electrode G2 and the semiconductor layer SML (step S120). The first region R1 opposes the first gate electrode G1, and the second region R2 opposes the second gate electrode G2. Thereby, the nonvolatile semiconductor memory device having a good charge holding characteristic can be manufactured.

The process of step S110 recited above changes variously with the configuration of a nonvolatile semiconductor memory device to be manufactured.

For example, in the case of the nonvolatile semiconductor memory device 102 of the first example, first, the second insulating layer I2 is formed on the semiconductor layer SML, the parent body film MF is formed thereon, and then the first insulating layer I1 is formed thereon. Then, a conductive film serving as the gate electrode GE is formed on the first insulating layer I1, and the conductive film is processed to form the gate electrodes GE (the first gate electrode G1 and the second gate electrode G2). The selection gate electrode SG is simultaneously formed at this time.

For example, in the case of the nonvolatile semiconductor memory devices 110 and 120 of the second and third examples, first, the electrode films WL (corresponding to the gate electrodes GE) and the inter-electrode insulating films 14 are alternatively stacked on the substrate 11 to form the stacked structure body ML. Then, the through-holes TH which pierce the stacked structure body ML along the Z-axis direction are formed, and the outside insulating film 43 (corresponding to the first insulating layer I1), the memory layer 48 (corresponding to the parent body film MF), and the inside insulating film 42 (corresponding to the second insulating layer I2) are formed in this order inside the through-hole TH. A semiconductor is filled in the remaining space of the through-hole TH, and the semiconductor pillar SP (corresponding to the semiconductor layer SML) is formed. Thus, in the manufacturing method of this embodiment, the configuration of Step S110 may be modified variously.

According to the embodiments, the nonvolatile semiconductor memory device having a good charge holding characteristic and the manufacturing method thereof can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the invention is not limited to these specific examples. For example, one skilled in the art may similarly practice the invention by appropriately selecting specific configurations of components included in nonvolatile semiconductor memory devices such as semiconductor layers, gate electrodes, selection gate electrodes, insulating layers, functional layers, parent bodies, and the like from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

The nonvolatile semiconductor memory device and the method for manufacturing the same described above as the embodiment of the invention can be suitably modified and practiced by those skilled in the art, and such modifications are also encompassed within the scope of the invention as long as they fall within the spirit of the invention.

Furthermore, various modifications and alterations within the spirit of the invention will be readily apparent to those skilled in the art. All such modifications and alterations should therefore be seen as within the scope of the invention. For example, additions, deletions, or design modifications of components or additions, omissions, or condition modifications of processes appropriately made by one skilled in the art in regard to the exemplary embodiments described above are within the scope of the invention to the extent that the purport of the invention is included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A nonvolatile semiconductor memory device, comprising:
a semiconductor layer;
a first insulating layer opposing the semiconductor layer;
a second insulating layer provided between the semiconductor layer and the first insulating layer;
a functional layer provided between the first insulating layer and the second insulating layer;
a first gate electrode, the first insulating layer being disposed between the first gate electrode and the semiconductor layer; and
a second gate electrode separated from the first gate electrode, the first insulating layer being disposed between the second gate electrode and the semiconductor layer,
a charge storability in a first region of the functional layer and a charge storability in a second region of the functional layer being different from a charge storability in a third region of the functional layer, the first region opposing the first gate electrode, the second region opposing the second gate electrode, and the third region being provided between the first region and the second region.

2. The device according to claim 1, wherein
the functional layer is formed from a parent body film, and
the charge storability in the first region and the charge storability in the second region are made to be higher than a charge storability in the parent body film by implementing at least one of applying an electric field between the first gate electrode and the semiconductor layer and between the second gate electrode and the semiconductor layer and applying a current between the first gate electrode and the semiconductor layer and between the second gate electrode and the semiconductor layer.

3. The device according to claim 1, wherein the charge storability in the first region and the charge storability in the second region are higher than the charge storability in the third region.

4. The device according to claim 1, wherein a trap density in the first region and a trap density in the second region are higher than a trap density in the third region.

5. The device according to claim 1, wherein the first region and the second region function as a charge storage layer.

6. The device according to claim 5, wherein the third region does not function as a charge storage layer.

7. The device according to claim 5, wherein the first insulating layer functions as a block insulating film and the second insulating layer functions as a tunnel insulating film.

8. The device according to claim 1, wherein
the functional layer is formed from a parent body film, and
a first portion and a second portion are formed in the first region and the second region by implementing at least one of applying an electric field between the first gate electrode and the semiconductor layer and between the second gate electrode and the semiconductor layer and applying a current between the first gate electrode and the semiconductor layer and between the second gate electrode and the semiconductor layer, and a charge storability in the second portion is lower than a charge storability in the first portion.

9. The device according to claim 8, wherein the first portion is divided by the second portion.

10. The device according to claim 1, further comprising a selection gate electrode separated from the first gate electrode and the second gate electrode, the first insulating layer being disposed between the selection gate electrode and the semiconductor layer,
a charge storability in a fourth region of the functional layer being lower than the charge storability in the first region and the charge storability in the second region, the fourth region opposing the selection gate electrode.

11. The device according to claim 10, wherein an electric field applied between the selection gate electrode and the semiconductor layer is lower than an electric field applied between the first gate electrode and the semiconductor layer and is lower than an electric field applied between the second gate electrode and the semiconductor layer.

12. The device according to claim 11, wherein a current applied between the selection gate electrode and the semiconductor layer is smaller than a current applied between the first gate electrode and the semiconductor layer and is smaller than a current applied between the second gate electrode and the semiconductor layer.

13. The device according to claim 1, wherein
the semiconductor layer is a semiconductor substrate,
the second insulating layer is disposed on the semiconductor layer,
the functional layer is disposed on the second insulating layer,
the first insulating layer is disposed on the functional layer,
the first gate electrode and the second gate electrode are disposed on the first insulating layer, and
a direction from the first gate electrode toward the second gate electrode is parallel to a major surface of the semiconductor substrate.

14. The device according to claim 1, further comprising;
an inter-electrode insulating film provided between the first gate electrode and the second gate electrode; and
a substrate,
the first gate electrode and the second gate electrode being disposed on the substrate,
a first direction from the first gate electrode toward the second gate electrode being perpendicular to a major surface of the substrate,
the semiconductor layer piercing the first gate electrode, the inter-electrode insulating film and the second gate electrode along the first direction,
the first insulating layer being disposed between the first gate electrode and a side face of the semiconductor layer and between the second gate electrode and a side face of the semiconductor layer.

15. The device according to claim 1, further comprising;
an inter-electrode insulating film provided between the first gate electrode and the second gate electrode; and
a substrate,
the first gate electrode and the second gate electrode being disposed on the substrate,
a first direction from the first gate electrode toward the second gate electrode being perpendicular to a major surface of the substrate,
the semiconductor layer opposing a side face of the first gate electrode along the first direction and a side face of the second gate electrode along the first direction,
the first insulating layer being disposed between the first gate electrode and a side face of the semiconductor layer and between the second gate electrode and a side face of the semiconductor layer.

16. A method for manufacturing a nonvolatile semiconductor memory device, comprising:
forming a structure body, the structure body including:
a semiconductor layer;
a first insulating layer opposing the semiconductor layer;
a second insulating layer provided between the semiconductor layer and the first insulating layer;
a parent body film provided between the first insulating layer and the second insulating layer;
a first gate electrode, the first insulating layer being disposed between the first gate electrode and the semiconductor layer; and
a second gate electrode separated from the first gate electrode, the first insulating layer being disposed between the second gate electrode and the semiconductor layer ; and
making a charge storability in a first region of the parent body film and a charge storability in a second region of the parent body film to be different from a charge storability in the parent body film by implementing at least one of applying an electric field between the first gate electrode and the semiconductor layer and between the second gate electrode and the semiconductor layer and applying a current between the first gate electrode and the semiconductor layer and between the second gate electrode and the semiconductor layer, the first region opposing the first gate electrode, and the second region opposing the second gate electrode.

17. The method according to claim 16, wherein the parent body film includes at least one of SiO₂ having an oxygen composition ratio higher than a stoichiometry ratio, SiO₂ containing an impurity, SiO₂ containing hydrogen, and SiN containing hydrogen.

18. The method according to claim 16, wherein the parent body film includes at least one of a stacked film of a silicon nitride film and a silicon oxide film; a stacked film of a silicon oxide film and a silicon nitride film containing fluorine; a silicon nitride film having a composition of excessive nitrogen; a silicon oxide film having a composition of excessive oxygen; and a stacked film of a silicon nitride film having a composition of excessive nitrogen and a silicon oxide film having a composition of excessive oxygen.

19. The method according to claim 16, wherein the parent body film includes at least one of a Si film, a Ge film and a metal film.

20. The method according to claim 16, wherein the implementing the at least one of applying the electric field and applying the current includes applying a positive pulse and a negative pulse alternatively in a plurality of times.
